(19) United States
(12) Patent Application Publication
(10) Pub. No.: US 2006/0160367 A1
(43) Pub. Date: Jul. 20, 2006

(54) Methods of treating semiconductor substrates

(75) Inventors: Chien M. Wai, Moscow, ID (US); Hiroyuki Ohde, Osaka (JP); Stephen J. Kramer, Boise, ID (US)

Correspondence Address: WELLS ST. JOHN P.S., 601 W. FIRST AVENUE, SUITE 1300, SPOKANE, WA, 99201, US

(73) Assignee: Micron Technology, Inc. and Idaho Research Foundation

(21) Appl. No.: 11/038,683

(22) Filed: Jan. 19, 2005

(51) Int. Cl. H01L 21/302; H01L 21/461; B44C 1/22

(52) U.S. Cl. 438/745; 216/58; 438/715

(57) ABSTRACT

The invention includes methods of treating semiconductor substrates with one or more reactants dispersed in supercritical fluid. A substrate can be provided within a reaction chamber having an interior periphery. The interior periphery can include a bottom region, a top region, and one or more sidewall regions between the bottom and top regions. The reaction chamber can be oriented in a gravitational field such that the field pulls from the top region toward the bottom region. The semiconductor substrate can be attached to one of the regions of the interior periphery other than the bottom region, and thereafter treated within the reaction chamber by exposing the semiconductor substrate to one or more reactants dispersed within a supercritical fluid.

### TECHNICAL FIELD

The invention pertains to methods of treating semiconductor substrates utilizing supercritical fluids.

### BACKGROUND OF THE INVENTION

There is continuing interest in utilizing supercritical fluids during treatment of semiconductor substrates. As is known to persons of ordinary skill in the art, a supercritical fluid is defined as any substance that is above its critical temperature (T_{c}) and critical pressure (P_{c}). T_{c} is the highest temperature at which a gas can be converted to a liquid by an increase in pressure, and P_{c} is the highest pressure at which a liquid can be converted to a traditional gas by an increase in the liquid temperature. In the so-called critical region there is only one phase, and it possesses properties of both gas and liquid.

Supercritical fluids differ from traditional fluids in several aspects. For example, the solvent power of a supercritical fluid will typically increase with density at a given temperature. Also, supercritical fluids can have higher diffusion coefficients than conventional solvents, which can enhance chemical reactions occurring therein. Additionally, deposition from within a supercritical fluid can allow for infiltration of very small, high aspect ratio features. This may be due to negligible surface tension during deposition and very high diffusivity. Due to its ability to fill high aspect ratio features, deposition from within a supercritical fluid can be used to fill sub-micron nano-features.

In particular applications, a supercritical fluid can have various materials dispersed therein and/or dissolved therein. For purposes of interpreting this disclosure and the claims that follow, the term “supercritical fluid” is utilized to refer specifically to a portion of a composition that is in a supercritical state (i.e., is utilized to refer to the supercritical component of a composition). Typically, materials dispersed and/or dissolved within a supercritical fluid will not be in a supercritical state, and accordingly will not be part of the supercritical fluid. However, it is noted that in particular applications one or more materials dispersed within a supercritical fluid can be in a supercritical state. In such applications, the dispersed material that is in the supercritical state will be part of the supercritical fluid.

Supercritical fluids can be utilized in numerous applications in semiconductor processing. For instance, supercritical fluids can have deposition reactants dispersed therein and be utilized for deposition of substances over semiconductor substrate surfaces. As another example, supercritical fluids can have etching reactants dispersed therein which are utilized for etching various materials associated with surfaces of a semiconductor substrates.

Supercritical fluids can comprise any of numerous compositions. Exemplary supercritical fluids can comprise, consist essentially of, or consist of one or more of CO₂, ammonia and an alkanol having from 1 to 5 carbon atoms. Exemplary alkanols are ethanol and methanol. Other exemplary materials that can be formed into supercritical fluids are isooctane, hexane, heptane, butane, methane, ethane, propane, ethene, propene, water, xenon, nitrous oxide, tetrafluoromethane, difluoromethane, tetrafluoroethane, pentafluoroethane, sulfur hexafluoride, CFC-12, HCFC-22, HCFC-123, HFC-116, HFC-134a, and diemethylether. An advantage of utilizing carbon dioxide for supercritical fluids, as opposed to other compositions, is that carbon dioxide has a relatively low critical temperature of 304.13K, (31° C.). Other advantages of carbon dioxide include it's high abundance, low critical pressure (72.8 atmospheres), and general non-toxicity.

An exemplary apparatus that can be utilized for treating a semiconductor substrate with supercritical fluid is shown in FIG. 1 as apparatus 10. Apparatus 10 comprises a reaction chamber 12. An inlet 14 extends into the reaction chamber, and an outlet 16 also extends into the reaction chamber. A valve 18 is shown extending across the inlet 14, and another valve 20 is shown extending across the outlet 16. In operation, materials are flowed into the chamber through inlet 14 and exhausted out of the chamber through outlet 16. Valves 18 and 20 permit controllable flow of materials into and out of the chamber. The flow of materials into the chamber is represented by an arrow 22, and the exhausting of materials out of the chamber is represented by an arrow 24.

A substrate holder 26 is provided within the chamber, and is shown holding a substrate 28. Substrate 28 can correspond to, for example, a semiconductor substrate. To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

Substrate holder 26 comprises a table 30 retained by a support structure 32. The table 30 can be heated with a heating apparatus (not shown) to enable substrate 28 to be maintained at a desired temperature during exposure of the substrate to materials within the chamber 12. The table 30 can, for example, comprise a 5×5 cm quartz heating table, and in some aspects can be part of a chuck.

In operation, a supercritical fluid having one or more substances dispersed therein is flowed into the chamber, and substrate 28 is exposed to such supercritical fluid and dispersed substances while being maintained at a desired temperature. Such exposure can, depending on the dispersed substances and the composition of exposed surfaces of substrate 28, form deposits over exposed surfaces of substrate 28 and/or etch various materials from exposed surfaces of substrate 28. Subsequently, unreacted reactant materials, together with products and supercritical fluid, can be exhausted from the chamber. The treated substrate can then be removed from the chamber.

There are numerous applications for utilization of supercritical fluids during treatment of semiconductor substrates. It is therefore desired to develop improved methods for treating semiconductor substrates with supercritical fluids.

### SUMMARY OF THE INVENTION

In one aspect, the invention encompasses a method of treating a semiconductor substrate. An apparatus is provided which comprises a reaction chamber. The reaction chamber includes an interior periphery that comprises a bottom region, a top region, and one or more sidewall regions between the top and bottom regions. The reaction chamber is oriented in a gravitational field such that the field pulls from the top region toward the bottom region. A semiconductor substrate is attached to one of the regions of the interior periphery other than the bottom region. The attached semiconductor substrate is treated by exposing the semiconductor substrate to a supercritical fluid having one or more reactants dispersed therein.

In one aspect, the invention encompasses another method of treating a semiconductor substrate. An apparatus is provided which comprises a reaction chamber. The reaction chamber comprises an interior periphery that includes a bottom half and a top half. The reaction chamber is oriented in a gravitational field such that the field pulls from the top half toward the bottom half. A semiconductor substrate is retained within the top half of the interior periphery. The retained semiconductor substrate is exposed to a supercritical fluid having one or more reactants dispersed therein.

In one aspect, the invention encompasses yet another method of treating a semiconductor substrate. An apparatus is provided which comprises a reaction chamber. The reaction chamber includes a bottom interior surface and a top interior surface. The reaction chamber is oriented in a gravitational field such that the field pulls from the top interior surface toward the bottom interior surface. A semiconductor substrate is retained proximate the top interior surface. The substrate has a surface which is to be treated, and such substrate surface faces downwardly within the reaction chamber toward the bottom interior surface. The retained semiconductor substrate is heated. While the semiconductor substrate is retained and heated, the substrate surface is exposed to a supercritical fluid having one or more reactants dispersed therein. Such arrangement can be beneficial for processes utilizing supercritical fluids for at least the reasons that convection currents can bring warmed materials upwardly toward the substrate, and gravity can pull particles downwardly and away from the substrate.

### BRIEF DESCRIPTION OF THE DRAWINGS

Preferred embodiments of the invention are described below with reference to the following accompanying drawings.

FIG. 1 is a diagrammatic, cross-sectional view of a prior art apparatus comprising a reaction chamber suitable for exposure of a semiconductor substrate to reactants dispersed within supercritical fluid.

FIG. 2 is a diagrammatic, cross-sectional view of an exemplary apparatus suitable for processing of some aspects of the present invention.

FIG. 3 shows a portion of the apparatus of FIG. 2 corresponding to the portion labeled “3” in FIG. 2, and modified to show an exemplary device which can be utilized for attaching a semiconductor substrate within the apparatus of FIG. 2.

FIG. 4 shows a portion of the apparatus of FIG. 2 corresponding to the portion labeled “3” in FIG. 2, and modified to show another exemplary structure which can be utilized for attaching a semiconductor substrate within the apparatus.

FIG. 5 is a diagrammatic, cross-sectional view of a reaction chamber illustrating various aspects that can be present in some embodiments of the present invention.

FIG. 6 is a diagrammatic, cross-sectional view of a reaction chamber having a semiconductor substrate retaining therein, and illustrating aspects of an embodiment of the present invention.

FIG. 7 is a diagrammatic view of an exemplary apparatus which can be utilized for treating a semiconductor substrate in accordance with an exemplary aspect of an embodiment of the present invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

In exemplary aspects, the invention includes new arrangements for retaining semiconductor substrates within reaction chambers during exposure to supercritical fluid conditions. Specifically, the invention includes aspects in which it is recognized that there can be advantages for providing a semiconductor substrate on a region of a reaction chamber other than a bottom of the chamber during exposure of the substrate to supercritical fluid conditions.

Prior art processes provide semiconductor substrates at the bottom of a reaction chamber during exposure to supercritical fluid processes, and then heat the substrate to achieve a desired temperature of the substrate during the exposure.

The present invention recognizes that convective currents within the reaction chamber will tend to carry heat upwardly within the chamber, and accordingly it can be more efficient to place a heated semiconductor substrate in an elevated region of a reaction chamber, rather than at the bottom of a reaction chamber. In particular exemplary aspects of the invention, a heating plate can be installed upside down at the top of a reaction chamber, and a substrate can be held on the upside down heating plate with a surface of the substrate being exposed in an upside-down arrangement within the reaction chamber. The substrate can then be heated, and the upside-down surface exposed to supercritical fluid and reactants dispersed within the supercritical fluid to treat the upside-down surface. Such treatment can include, for example, deposition of materials on the upside-down surface and/or etching of materials from the upside-down surface.

The upside-down arrangement and other arrangements of the present invention provide various advantages over conventional arrangements of semiconductor substrates within the supercritical-fluid-treatment reaction chambers, with respect to, for example, heat efficiency and purity of deposited films.

Among the advantages that methodology of the present invention can provide is that insoluble impurities (such as large particles, e.g., metals, semiconductors and insulators, formed by homogeneous reactions in the supercritical phase) will fall to the bottom of the chamber rather than accumulate in or on a growing film. This can avoid a prior art problem, in that large particles and/or other insoluble impurities embedded in or precipitated onto a thin film can cause quality problems of the film in morphology and purity. Also among the advantages is that the efficiency of heating the substrate will be improved as convection currents within the apparatus will move heat toward the substrate rather than away from the substrate. Specifically, since the density gradient due to heating causes hotter supercritical fluid to rise, the hotter supercritical fluid will be intercepted by a substrate at an upper region of a reaction chamber, which can be particularly advantageous if the substrate is at the top of the reaction chamber. The reaction chamber will typically have an upper stainless steel wall. Heat conduction in the thick stainless steel wall is relatively slow, and accordingly heat will stay around the upside-down heat plate installed on the upper interior wall of the reaction chamber.

In particular exemplary aspects of the invention, the arrangements of the present invention of placing substrates within upper regions of reaction chambers can be used to make better quality films on semiconductor devices at lower temperatures than would be accomplished utilizing conventional arrangements. Such can be particularly advantageous for depositing materials in nanostructures or on surfaces of various solid materials.

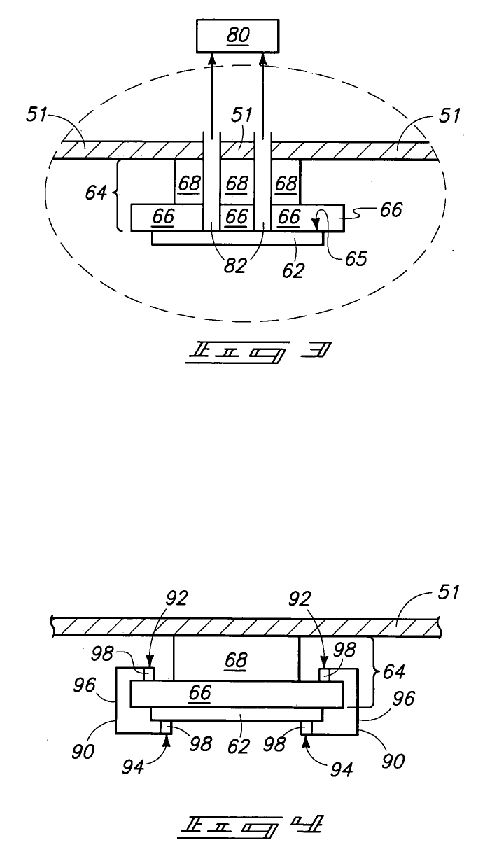

An exemplary reaction chamber of an embodiment of the present invention is described with reference to an apparatus 50 of FIG. 2. Such apparatus includes a reaction chamber 52 surrounded by a wall 51. The wall can comprise, for example, stainless steel.

The reaction chamber has an interior periphery that includes a bottom region 53, a top region 55, and sidewall regions 57 and 59 between the top and bottom regions. It is to be understood that the apparatus 50 is shown in cross-sectional view, and that sidewalls 57 and 59 would wrap around to join with one another in the actual apparatus. Accordingly, the sidewalls 57 and 59 can also be considered to be part of a single sidewall extending entirely around the reaction chamber, even though the sidewalls appear separate from one another in the cross-sectional view of FIG. 2.

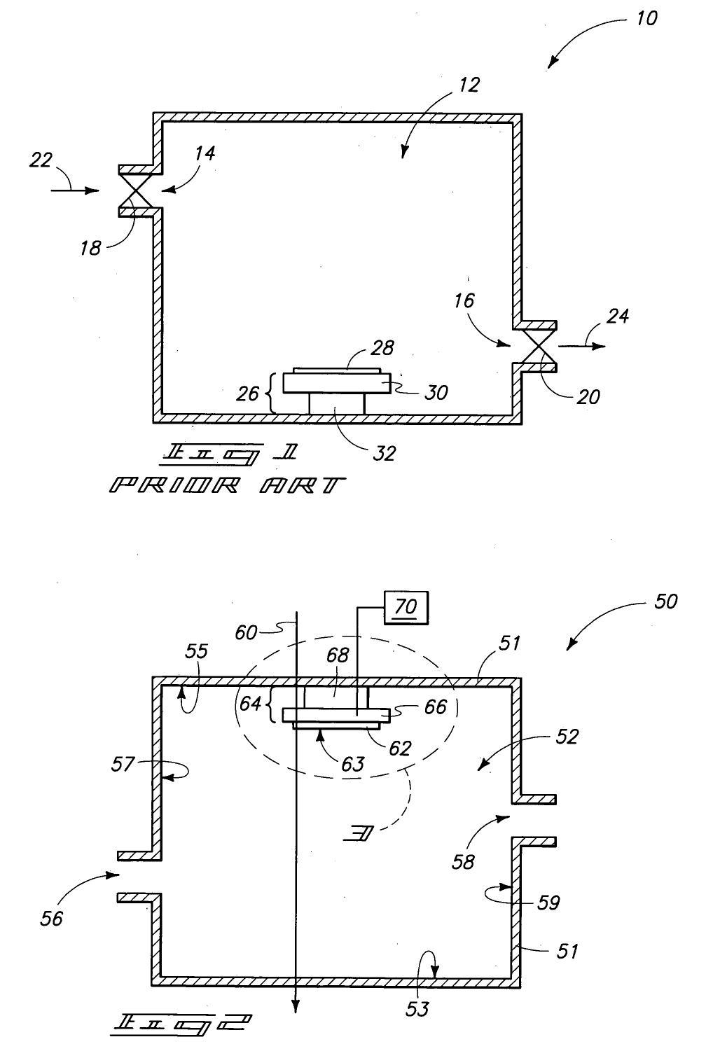

The reaction chamber includes an inlet 56 and an outlet 58, similar to the inlet 14 and outlet 16 described previously with reference to FIG. 1. Valves are not shown across the inlet 56 and outlet 58, but it is to be understood that valves analogous to the valves 18 and 20 of FIG. 1 would typically be present across the inlet and outlet, respectively.

The apparatus 50 is oriented relative to the gravitational field of the earth so that the gravitational field pulls from the top region 55 toward the bottom region 53. The gravitational field is illustrated diagrammatically by the vector 60 in FIG. 2.

A semiconductor substrate 62 is provided within the reaction chamber 52 and attached to one of the regions of the interior periphery other than the bottom region 53 (i.e., is attached to one of the regions 57, 59 or 55). In the shown aspect of the invention, the semiconductor substrate is attached to the top region 55 through a support structure 64. Such support structure includes a table 66 and a supporting element 68 adhering the table to the upper chamber wall.

The table 66 can correspond to a heating plate, and can be attached to a temperature control unit 70. The temperature control unit can be considered to be proximate the table, in that the temperature control unit is in a location where it can control a temperature of the table. The substrate 62 can be heated utilizing the temperature control unit 70 in combination with the heating plate 66.

In operation, a supercritical fluid having reactant dispersed therein is provided within chamber 52 and utilized to treat the substrate 62. The substrate 62 has a surface 63 facing downwardly within the chamber toward bottom region 53. The treatment of the semiconductor substrate can comprise exposure of surface 63 to one or more reactants dispersed within the supercritical fluid. Such treatment can, for example, etch one or more materials from surface 63 and/or deposit one or more materials over surface 63.

In particular aspects, substrate 62 will be heated during the exposure of surface 63 to the supercritical fluid and various reactants. The apparatus of FIG. 2 advantageously enables convection currents within reaction chamber 52 to keep heat at the upper region of the chamber proximate the substrate. The apparatus of FIG. 2 also advantageously enables precipitates falling out of the supercritical fluid to be pulled by gravity away from substrate 62 and toward the bottom of the chamber, rather than falling onto the substrate 62 as would occur in prior art processes in which the substrate was at the bottom of the chamber. The precipitates can come from various sources and can, for example, include one or more insoluble impurities formed in the reaction chamber and/or insoluble materials from external of the chamber.

The supercritical fluid can comprise any suitable fluid, and the reactant can comprise any suitable reactant or combination of reactants. In particular aspects the supercritical fluid will comprise carbon dioxide; and the various reactants will comprise hydrogen and one or more metal precursors for forming metal-containing deposits over the surface 63, and/or will comprise etchants for removing various materials from surface 63. Other exemplary reactants that be utilized with the supercritical fluid include oxygen, water, and semi-metal precursors (the semi-metal precursors can be useful in forming semiconductor and insulator materials).

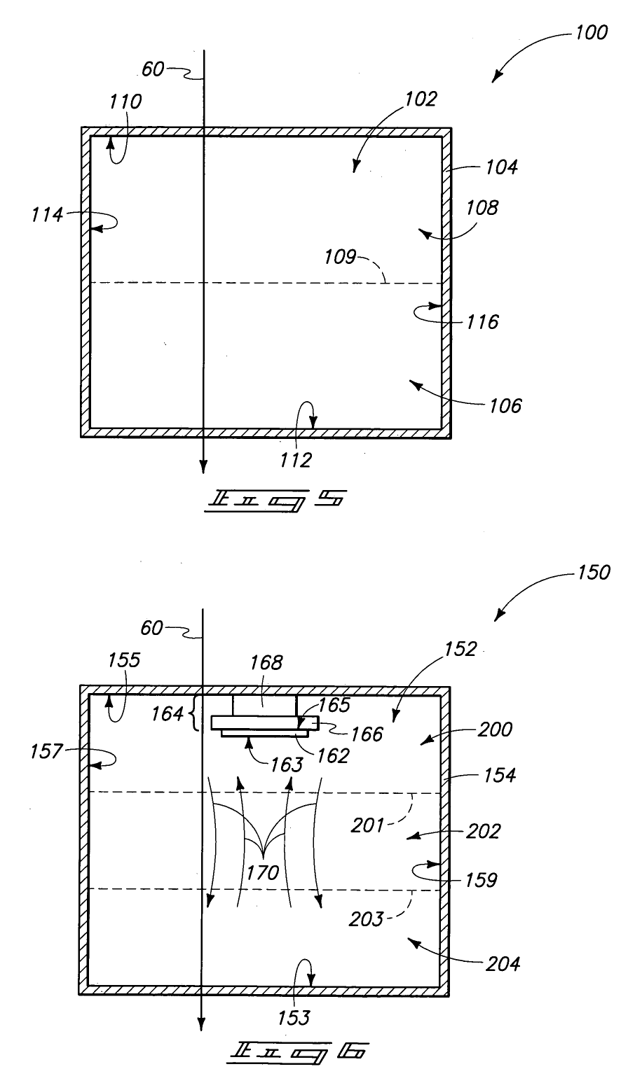

Substrate 62 can be attached to support 64 through any suitable attachment structure or combination of structures. FIGS. 3 and 4 illustrate exemplary attachment structures which can be utilized, and specifically illustrate an expanded region of the FIG. 2 apparatus (with such expanded region being the region designated as “3” in FIG. 2) together with exemplary attachment structures.

Referring to FIG. 3, an exemplary attachment structure is a vacuum system comprising a vacuum suction apparatus 80 and vacuum nozzles or tubes 82 extending through sidewall 51 and support structure 64 to a surface of substrate 62. In operation, vacuum from system 80 pulls through tubes 82 against the surface of substrate 62 to retain substrate 62 against table 66. The surface of substrate 62 pulled by the vacuum can be referred to as a backside surface 65.

System 80 can, in some aspects, correspond to a venturi system, and accordingly tubes 82 can be considered to be venturi nozzles of such system. In such aspects, the venture system can be considered one example of a vacuum system.

The tubes 82 are provided in sufficient number to retain substrate 62. In some aspects, only one tube is utilized and in other aspects multiple tubes are utilized.

Referring next to FIG. 4, substrate 62 is shown retained to table 66 with a pair of clips 90. Such clips comprise segments 92 against a backside surface of the table, and segments 94 against a frontside surface of the substrate in the shown aspect of the invention. The clips also comprise lengths 96 of wire or other suitable material exerting spring tension between the segments 92 and 94. The segments 92 and 94 can comprise pads 98 as shown, which can alleviate potential scratching of the surfaces exposed to the clip that could occur in the absence of such pads.

Although two clips are shown, it is to be understood that any suitable number of clips can be utilized for retaining substrate 62. In some aspects only one clip will be utilized, and in other aspects multiple clips will be utilized. Also, it is to be understood that the embodiments of FIGS. 3 and 4 can be combined so that a substrate is retained with both a vacuum system and one or more clips.

FIG. 5 illustrates an apparatus 100 illustrating further aspects of an embodiment of the invention. Apparatus 100 comprises a reaction chamber 102 having a sidewall 104 extending there-around. The reaction chamber comprises an interior periphery that includes a bottom half 106 and a top half 108. The top half and bottom half are illustrated as being separated from one another by a demarcation line 109. Line 109 is an imaginary line provided to assist the reader in differentiating the bottom half from the top half.

The reaction chamber 100 is oriented in a gravitational field so that the field pulls from the top half to the bottom half. The gravitational field is illustrated by the vector 60 in FIG. 5 and would correspond to the gravitational field of the earth. In operation, a semiconductor substrate (not shown) is retained within the top half of the interior periphery of the reaction chamber 102, and then exposed to a supercritical fluid having one or more reactants dispersed therein to treat the semiconductor substrate.

The interior periphery of the reaction chamber 102 can be considered to comprise a top surface 110, a bottom surface 112, and sidewall surfaces 114 and 116 connecting the top and bottom surfaces to one another. The semiconductor substrate retained within the top half of the reaction chamber can be retained against the sidewall surfaces and/or the top surface. In a particular aspect of the invention, the semiconductor substrate is retained against the top surface 110 utilizing structures analogous to the retaining structures discussed above with reference to FIGS. 2-4. In other aspects, the substrate is retained against the sidewall surface 114 or 116 utilizing retaining structures analogous to the retaining structures discussed above with reference to FIGS. 2-4.

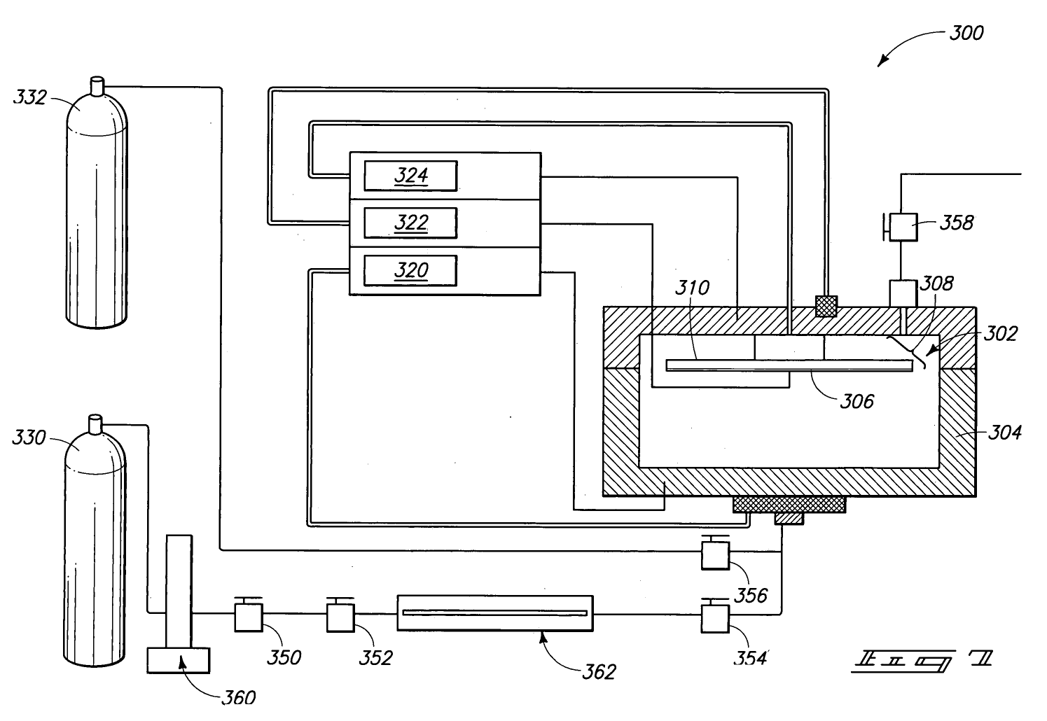

FIG. 6 illustrates an apparatus 150 showing further exemplary aspects of an embodiment of the present invention. The apparatus 150 comprises a reaction chamber 152 surrounded by a sidewall 154. The chamber comprises a bottom interior surface 153, a top interior surface 155, and sidewall interior surfaces 157 and 159. The reaction chamber is oriented in a gravitational field such that the field pulls from the top interior surface toward the bottom interior surface, and such gravitational field is diagrammatically illustrated with the vector 60 in FIG. 6.

A semiconductor substrate 162 is shown retained proximate top surface 155 with a supporting structure 164. Structure 164 is analogous to the structure 64 described above with reference to FIG. 2, and accordingly comprises a table 166 attached to upper surface 155 through an attachment structure 168. Substrate 162 can be retained on table 166 through any suitable retaining structure, including, for example, retaining structures of the type described above with reference to FIGS. 3 and 4.

Substrate 162 can correspond to a semiconductor substrate. Substrate 162 comprises a surface 163 facing downwardly toward the bottom interior surface 153, and comprises another surface 165 in opposing orientation relative to surface 163. Surface 163 can be referred to as a front-side surface and surface 165 can be referred to as a back-side surface.

In operation, a supercritical fluid having one or more reactants dispersed therein is provided within chamber 152 to treat front-side surface 163 of substrate 162. The retained substrate 162 is heated during the treatment of front-side surface 163, with such heating occurring by, for example, utilization of a heating apparatus analogous to the apparatus 70 described above with reference to FIG. 2.

The heating forms convective currents 170 in the reaction chamber. The convective currents carry heated materials upwardly within the chamber, and carry cooler materials downwardly. Accordingly, the heat within the chamber concentrates near substrate 162 through improved efficiency of the heating relative to prior art structures of the type described above with reference to FIG. 1 where the substrate is at a bottom of the reaction chamber.

Convective flow tends to be greater for dense fluids than for less dense fluids, and accordingly the convective flow can be highly substantial for the relatively dense supercritical fluids. The methodology of the present invention can thus be significantly more efficient than prior art methodology of the type described above with reference to FIG. 1.

The reaction chamber is shown divided into three regions 200, 202 and 204, which are illustrated to be separated from one another by demarcation lines 201 and 203. The region 200 can be considered an uppermost region within the chamber, the region 204 can be considered a lowermost region within the chamber, and the region 202 can be considered a mid-region within the chamber. In operation, the region 200 will typically be the hottest region within the chamber, the region 204 will be the coolest region within the chamber, and the region 202 will comprise a temperature gradient extending from the cooler region to the hotter region.

Another exemplary aspect of the present invention is described with reference to FIG. 7. Specifically, FIG. 7 shows an apparatus 300 comprising a reaction chamber 302 surrounded by a sidewall 304.

A semiconductor substrate 306 is retained within the chamber on a retaining structure 308, and specifically is shown retained proximate an uppermost surface of the chamber. The retaining structure 308 comprises a heating table (or chuck) 310 which can, in particular aspects of the invention, be a 5 cm by 5 cm square quartz heating table. Chamber 304 can be a stainless steel reactor having a volume of about 180 milliliters.

A plurality of temperature controllers 320, 322 and 324 are provided to control temperatures of a lower region of the reactor, a substrate within the reactor, and an upper region of the reactor, respectively.

A source 330 of fluid for the supercritical fluid is provided proximate the chamber 302, and such source can comprise, for example, a tank of carbon dioxide. Also, a source 332 of reactant is provided proximate the chamber. Such can comprise, for example, a tank of hydrogen (H₂) gas. It is to be understood that multiple sources of supercritical fluid and/or multiple sources of reactant can be provided in various aspects of the invention.

A plurality of valves 350, 352, 354, 356 and 358 are shown. Such valves can enable control of flow of the various materials into and out of the reaction chamber. It is to be understood that the valves are provided for diagrammatic purposes, and that more than the shown number of valves or less than the shown number of valves can be utilized in various aspects of the invention.

A pump 360 is diagrammatically illustrated. Such pump can enable supercritical fluid to be flowed into chamber 302 at sufficiently high pressure to maintain supercritical characteristics of the fluid. The pump can correspond to, for example, a Teledyne ISCO high pressure syringe pump.

A tubular injection vessel 362 is illustrated downstream of the source 330 of fluid, and along the flow path of the fluid from the source to the reaction chamber. The downstream injection vessel can, in particular aspects, correspond to a 20 milliliter volume tubular injection vessel, and can be utilized for mixing various reactants into the fluid.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A method of treating a semiconductor substrate, comprising:
providing an apparatus comprising a reaction chamber; the reaction chamber including an interior periphery that comprises a bottom region, a top region, and one or more sidewall regions between the bottom region and top region; the reaction chamber being oriented in a gravitational field such that the field pulls from the top region toward the bottom region;
attaching a semiconductor substrate to one of the regions of the interior periphery other than the bottom region; and
treating the attached semiconductor substrate by exposing the semiconductor substrate to a supercritical fluid having one or more reactants dispersed therein.

2. The method of claim 1 wherein the treating forms a deposit over at least a portion of the semiconductor substrate.

3. The method of claim 1 wherein the treating etches one or more materials associated with the semiconductor substrate.

4. The method of claim 1 wherein the attaching comprises attachment of the semiconductor substrate to the top region of the interior periphery.

5. The method of claim 1 further comprising heating the semiconductor substrate during the treating of the semiconductor substrate.

6. The method of claim 1 wherein:
the apparatus comprises a substrate-retaining table along the top region of the interior periphery of the reaction chamber;
the apparatus comprises a temperature control unit proximate the table;
the attaching comprises attaching the semiconductor substrate to the table; and
the semiconductor substrate is heated with the temperature control unit during the treating of the semiconductor substrate.

7. The method of claim 1 wherein the supercritical fluid comprises carbon dioxide.

8. A method of treating a semiconductor substrate, comprising:
providing an apparatus comprising a reaction chamber; the reaction chamber comprising an interior periphery that includes a bottom half and a top half; the reaction chamber being oriented in a gravitational field such that the field pulls from the top half toward the bottom half;
retaining a semiconductor substrate within the top half of the interior periphery; and
while the semiconductor substrate is retained within the top half of the interior periphery, exposing the semiconductor substrate to a supercritical fluid having one or more reactants dispersed therein to treat the semiconductor substrate.

9. The method of claim 8 wherein the treating forms a deposit over at least a portion of the semiconductor substrate.

10. The method of claim 8 wherein the treating etches one or more materials associated with the semiconductor substrate.

11. The method of claim 8 wherein:
the interior periphery comprises a top surface within the top half;
the apparatus comprises one or more structures associated with the top surface for retaining the semiconductor substrate; and
the semiconductor substrate is retained proximate the top surface with said one or more structures.

12. The method of claim 11 wherein the one or more structures include at least one clip.

13. The method of claim 11 wherein the one or more structures include at least one vacuum nozzle of a vacuum system.

14. The method of claim 11 wherein the one or more structures include at least one venturi nozzle of a venturi system.

15. The method of claim 8 further comprising heating the semiconductor substrate during the treating of the semiconductor substrate.

16. The method of claim 8 wherein:
the apparatus comprises a substrate-retaining table within the top half of the interior periphery of the reaction chamber;
the apparatus comprises a temperature control unit proximate the table; and
the semiconductor substrate is heated with the temperature control unit during the treating of the semiconductor substrate.

17. The method of claim 8 wherein the supercritical fluid comprises carbon dioxide.

18. A method of treating a semiconductor substrate, comprising:
providing an apparatus comprising a reaction chamber; the reaction chamber comprising a bottom interior surface and a top interior surface; the reaction chamber being oriented in a gravitational field such that the field pulls from the top interior surface toward the bottom interior surface;
retaining a semiconductor substrate proximate the top interior surface; the substrate having a surface which is to be treated and said substrate surface facing downwardly within the reaction chamber toward the bottom interior surface;
heating the retained semiconductor substrate; and
while the semiconductor substrate is retained and heated, exposing the semiconductor substrate surface to a supercritical fluid having one or more reactants dispersed therein to treat the semiconductor substrate surface.

19. The method of claim 18 wherein the treating forms a deposit over at least a portion of the semiconductor substrate surface.

20. The method of claim 18 wherein the treating etches one or more materials associated with the semiconductor substrate surface.

21. The method of claim 18 wherein the retaining of the semiconductor substrate includes retaining the semiconductor substrate with at least one clip.

22. The method of claim 18 wherein the retaining of the semiconductor substrate includes retaining the semiconductor substrate with at least one vacuum system.

23. The method of claim 18 wherein the retaining of the semiconductor substrate includes retaining the semiconductor substrate with at least one venturi system.

24. The method of claim 18 wherein:
the apparatus comprises a substrate-retaining table along the top surface of the interior periphery of the reaction chamber;
the apparatus comprises a temperature control unit proximate the table; and
the heating of the semiconductor substrate comprises utilization of the temperature control unit.

25. The method of claim 18 wherein the supercritical fluid comprises carbon dioxide.
